(19) United States
(12) Patent Application Publication
(10) Pub. No.: US 2025/0371463 A1
(43) Pub. Date: Dec. 4, 2025

(54) System for Engineering Proposal Generation

(71) Applicant: Spatial Business Systems, LLC, Littleton, CO (US)

(72) Inventors: Trevor Scullion, Carlisle (CA); Albert Eliasen, Chanhassen, MN (US); Serguei Sokolov, Manotick (CA)

(73) Assignee: Spatial Business Systems, LLC, Littleton, CO (US)

(21) Appl. No.: 19/222,833

(22) Filed: May 29, 2025

Related U.S. Application Data
(60) Provisional application No. 63/652,944, filed on May 29, 2024.
(60) Provisional application No. 63/664,218, filed on Jun. 26, 2024.

(51) Int. Cl. G06Q 10/0631; G06F 30/13; G06Q 10/10; G06Q 50/08; G06T 11/00; G06T 17/05

(52) U.S. Cl. CPC G06Q 10/06313; G06F 30/13; G06Q 10/103; G06Q 50/08; G06T 11/00; G06T 17/05; G06T 2200/24; G06T 2210/04

(57) ABSTRACT

The present invention provides a system and method for generating proposals for infrastructure modalities, such as electrical substations, using advanced artificial intelligence. It includes an input interface for data collection, a lightweight generative or rendering pipeline for creating preliminary 2D designs, and a generative model selected from diffusion, transformer-based, GAN or other architectures for refining these into detailed 3D models and generating preliminary designs. The system evaluates designs against predefined criteria to ensure compliance and feasibility. Supported by a cloud-based infrastructure for robust data processing and integration with third-party services, this system enhances the efficiency, accuracy, and compliance of modality planning and proposal generation.

### CROSS REFERENCE TO RELATED APPLICATIONS

This application claims priority to U.S. Provisional Patent Application No. 63/652,944 filed on May 29, 2024 and U.S. Provisional Patent Application No. 63/664,218 filed on Jun. 26, 2024, the entire contents of each of which are hereby incorporated by reference in their entirety.

### BACKGROUND OF THE INVENTION

### Field of the Invention

The present invention relates generally to the field of proposal generation for utilities and engineering projects. More specifically, it pertains to a platform designed to streamline and optimize the process of creating detailed and compliant proposals for utility and engineering projects, particularly those involving substations and grid systems.

### Description of the Related Art

In the utilities and engineering sectors, the creation of proposals for projects, such as substation designs and grid enhancements, is a complex and labor-intensive process. Typically, these proposals are extensive documents, often exceeding tens of pages, filled with intricate details specific to the grid, utility, and location. Each proposal must consider the unique design context of the substation involved, adhering to a multitude of industry standards and customer specifications.

The process of proposal generation is not only time-consuming but also costly. Firms often invest significant resources, sometimes upwards of $100,000, in labor to develop preliminary designs necessary for the proposal. These preliminary designs must include permitting, design documentation, and budget estimations, which are crucial for obtaining project approvals.

Moreover, the proposal process is highly iterative, involving repeated cycles of request for proposals (RFPs), proposal submissions, and revisions. This iterative nature adds to the duration and complexity of the process, requiring access to real-time information to continuously update and refine the proposal content.

Despite the need for precision and compliance in these proposals, the existing methods remain inefficient. The substantial amount of work required before even being selected for construction underscores the need for a more streamlined, efficient approach. Current systems and methodologies fail to adequately address the multidimensional challenges of designing cost-efficient solutions that meet all specified requirements.

For example, the initial planning of electrical substations is a complex engineering task that involves the integration of multiple engineering disciplines and adherence to strict regulatory and safety standards. Traditionally, generating proposals for substation designs has been a labor-intensive process requiring substantial input from engineers and planners/designers to ensure that each substation meets the specific operational requirements of its location and function. The process encompasses the arrangement of various connected components, including transformers, switches, and other electrical equipment, within a defined geographical area.

Current planning methods largely rely on manual processes supported by computer-aided design (CAD) and/or Geographic Information System (GIS) software, which, while beneficial, still require significant human intervention and expertise. These traditional methods are often time-consuming and prone to human error, leading to inefficiencies in design adjustments and scalability issues when adapting designs to new components, technologies or regulatory changes or public reviews. Furthermore, the increasing complexity of electrical networks and the introduction of smart grid technologies demand the understanding of new industry standards and more adaptable and intelligent proposal solutions that can integrate with these standards to produce optimized substation layouts for planning, performance, and cost.

The traditional approach to substation design and proposal generation typically begins with a manual assessment of the project requirements and the geographical area, requiring a significant expenditure of time related to tasks performed by humans. In many cases, engineers and designers must consider a myriad of factors including environmental impact, local infrastructure, and specific electrical needs of the area. This initial assessment is followed by the detailed arrangement of substation components using CAD/GIS tools. While CAD/GIS software provides a visual representation and some level of automation in design, it still requires extensive manual input for each unique project scenario, making the process both time-consuming and susceptible to errors.

Moreover, as electrical grids become increasingly complex with the integration of renewable energy sources and smart technologies, the limitations of traditional methods become more apparent. These systems often lack the flexibility to quickly adapt to new standards or incorporate advanced technologies like smart grid components, which are essential for modern electrical networks. This rigidity can lead to prolonged project timelines and increased costs due to the need for frequent revisions and updates.

The reliance on manual processes and traditional design tools also poses significant challenges in scalability. As firms take on more projects or larger-scale developments, the manual nature of these methods can lead to bottlenecks, where the capacity to generate proposals does not efficiently scale with demand. This inefficiency is exacerbated by the need for highly specialized knowledge and expertise in both engineering principles and regulatory standards, which can be a barrier to quickly training new staff or adapting to evolving industry practices.

Given these challenges, there is a pressing need for proposal generation solutions that can automate and optimize the planning process, especially in association with proposals relevant to complex environments such as electrical substations. Such solutions should not only reduce the reliance on manual input but also enhance the adaptability, ability to encourage compliance with applicable regulations, and accuracy of the proposals.

Resultantly, there exists a significant need for an innovative solution that can simplify and expedite the proposal generation process in the utilities and engineering sectors. Such a solution should be capable of integrating industry standards and customer specifications seamlessly into the proposal design. It should also facilitate the creation of preliminary designs, enabling the efficient generation of accompanying documentation and budget estimations.

A more desirable mechanism than those which currently exist would reduce the currently problematic labor and time costs associated with proposal preparation, enhance the accuracy and compliance of the proposals, and support the iterative nature of the RFP process through real-time data integration and sophisticated design tools. Relatedly, there remains a need to streamline the proposal process. Such mechanism would likely address a present desire in the relevant industry to increase the chances of winning bids and successfully execute projects.

There remains a clear and present need for a mechanism that can transform the cumbersome, costly, and iterative process of proposal generation into a more streamlined, cost-effective, and efficient procedure, thereby benefiting utilities and engineering firms significantly by reducing the time and cost expenditure in their preparing their project engagements.

### SUMMARY OF THE INVENTION

Aspects of the invention relate to system designed to enhance the process of generating proposals for electrical substations. This system leverages advanced artificial intelligence technologies, including an agentic system with a Large Language Model(LLM), a lightweight generative or rendering pipeline that produces low-latency 2-D and/or 3-D previews and a generative model (e.g., diffusion, transformer-based, or adversarial), to streamline and optimize the creation of detailed proposals for projects related to the design and development of electrical substation plans.

The system comprises input mechanisms comprising a user interface that collects essential data such as geographical location, site dimensions, environmental constraints, and specific engineering standards provided by a user. A natural language processor, coupled with a multi-agent LLM facilitates guided interactions in accordance with embodiments of the invention to ensure the accurate and complete collection of final input data from users. This data is then processed by the lightweight generative or rendering pipeline that produces low-latency 2-D and/or 3-D previews, which generates preliminary 2D plan view designs. These initial designs are further refined by the generative model, which consists of a Generator and a Discriminator. The Generator uses the input parameters to create detailed 3D models and 2D drawing sets, while the Discriminator evaluates these designs against predefined criteria to ensure they meet all necessary standards for feasibility, compliance, and optimization.

The system in its preferred embodiment further comprises cloud-based backend infrastructure, which supports the extensive data processing requirements and integrates with third-party services such as Engineering analysis, geographic information systems (GIS) and design tools. This infrastructure ensures that the system operates efficiently and reliably, providing timely and accurate proposal outputs.

The preferred embodiment improves the efficiency, accuracy, and capability to achieve compliant preliminary plans incorporated into generated proposals associated with the development of electrical substations, making it easier for engineering firms to respond to project bids with appropriate consideration of regulatory requirements.

### BRIEF DESCRIPTION OF THE FIGURES

FIG. 1 depicts a dashboard user interface in an embodiment of the invention.

FIG. 2 depicts a mapping user interface in an embodiment of the invention.

FIG. 3 depicts a chat user interface in an embodiment of the invention.

FIG. 4 depicts a substation design as an overlay over a surface area rendering within a user interface in an embodiment of the invention.

FIG. 5 depicts a user interface comprising the text of a proposal in an embodiment of the invention.

FIG. 6 depicts a substation design as an overlay over a surface area as generated by the system for inclusion within a proposal in accordance with an exemplary embodiment of the invention.

FIG. 7 depicts a top-down schematic view as generated by the system for inclusion within a proposal in accordance with an exemplary embodiment of the invention.

FIG. 8 depicts a cost estimate schedule for inclusion within a proposal as generated by the system in accordance with an exemplary embodiment of the invention.

### DETAILED DESCRIPTION

The preferred embodiment of the invention comprises a system leveraging artificial intelligence configured to enhance the process of generating proposals for infrastructure modalities, and in particular electrical substations. The generation of proposals for the design and implementation of electrical substations is an intended use of the preferred embodiment of the system. In various aspects, such embodiment of the system is configured to address complex and multifaceted challenges inherent in the design of modality projects and the generation of proposals therefor. By automating and optimizing the proposal creation process with the assistance of artificial intelligence technologies, in an embodiment the system addresses issues of efficiency, accuracy, and compliance associated with modality design project proposals. It streamlines the integration of relevant inputs such as geographical data, electrical requirements, and regulatory standards into cohesive and optimized proposals as outputs. Such capabilities as aspects of the system not only reduce the time and labor traditionally required for proposal preparation but also are intended to improve the likelihood of meeting client specifications and the success of the proposals, in particular aiding engineering firms in association with an intended use. The system's adaptability extends beyond electrical substations, making it highly effective for generating proposals for other infrastructure domains, such as Gas Regulator Stations. Aspects of embodiments including the conditional Variational Auto-encoder (cVAE) and the conditional Generative Adversarial Network (cGAN) can adeptly handle the specific requirements of gas infrastructure projects. In similar fashion, these projects often require initial parameters, and location constraints, such as safety and engineering standards, environmental impact considerations, and spatial requirements. By inputting these tailored parameters into the system, it can generate optimized and compliant designs for other infrastructure modalities such as Gas Regulator Stations, ensuring the resulting proposals meet the stringent requirements typical of such infrastructure.

### DETAILED DESCRIPTION

The preferred embodiment of the invention leverages artificial intelligence to enhance the process of generating proposals for infrastructure modalities, particularly electrical substations. The system components in an embodiment of the invention are illustrated across several figures as follows:

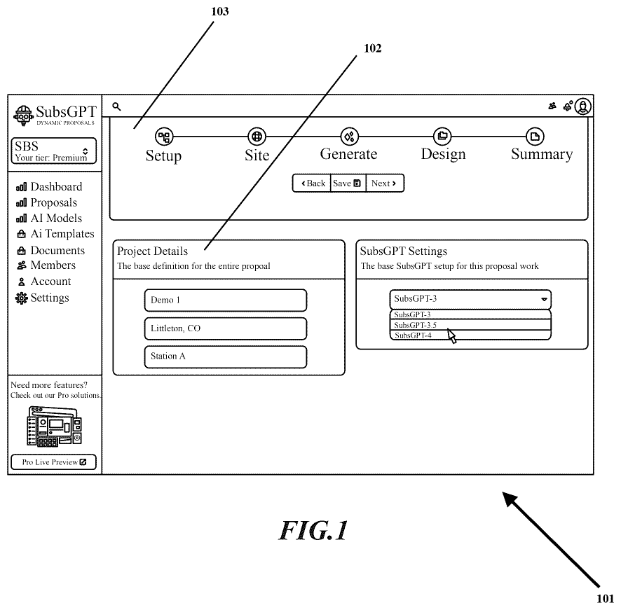

FIG. 1 depicts the dashboard interface of the system in an embodiment, showing the project details panel 102, setup navigation menu 103 that allow users to initiate and configure new proposals.

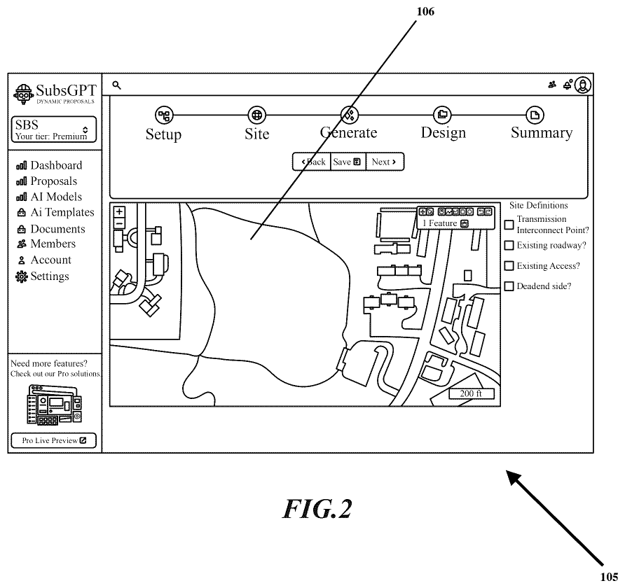

FIG. 2 illustrates the site mapping interface 105 providing a site map 106 in an embodiment where users can define site parameters and select features for the proposed infrastructure location.

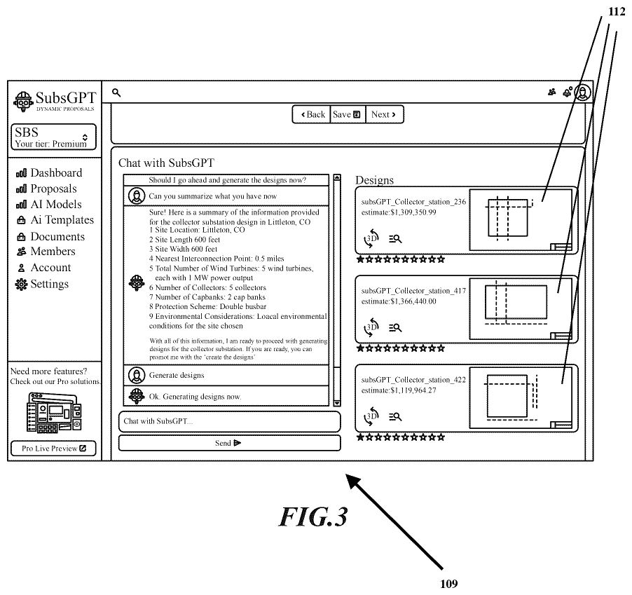

FIG. 3 shows the chat interface 109 in an embodiment that enables natural language interaction between users and the system for gathering project requirements and displaying generated design previews 112.

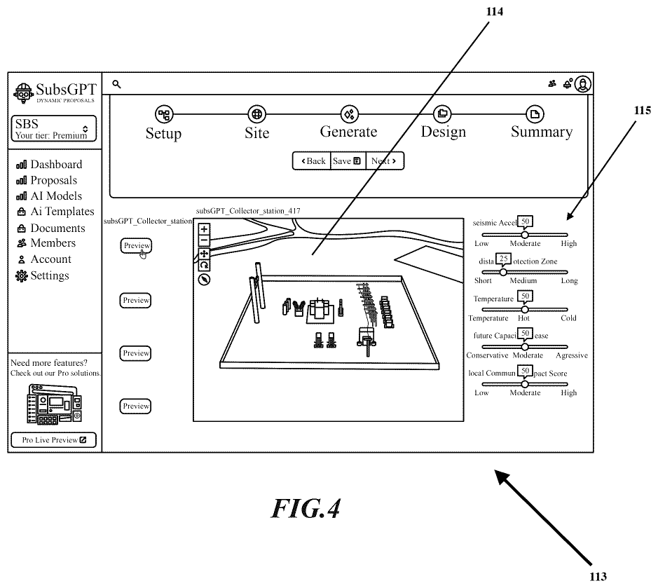

FIG. 4 presents the design preview interface 113 in an embodiment with parameter controls 114 that enable users to adjust and refine generated designs.

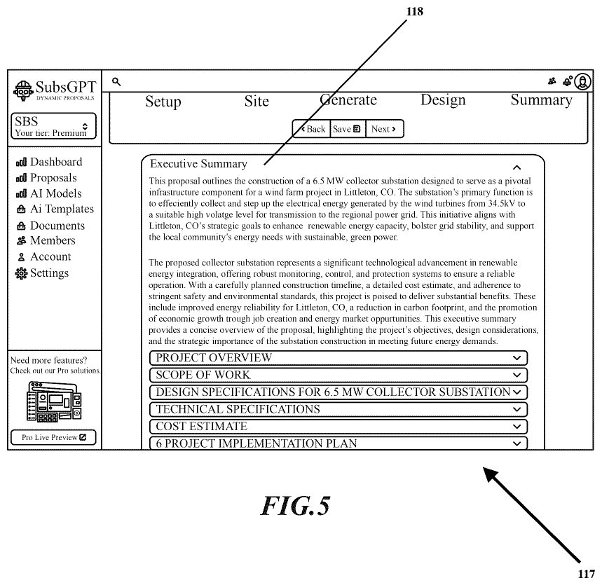

FIG. 5 depicts the proposal interface 118 in an embodiment that presents the generated content in a structured format including executive summary and project specifications.

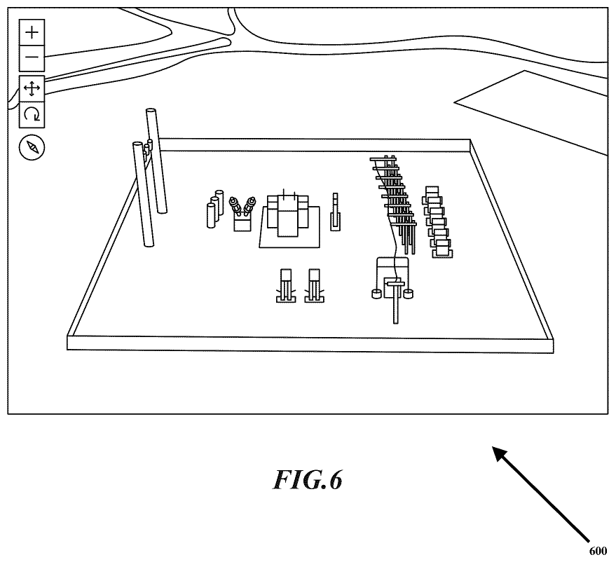

FIG. 6 shows a generated 3D design output with component layout 600 in an embodiment, illustrating the detailed spatial arrangement of the proposed infrastructure.

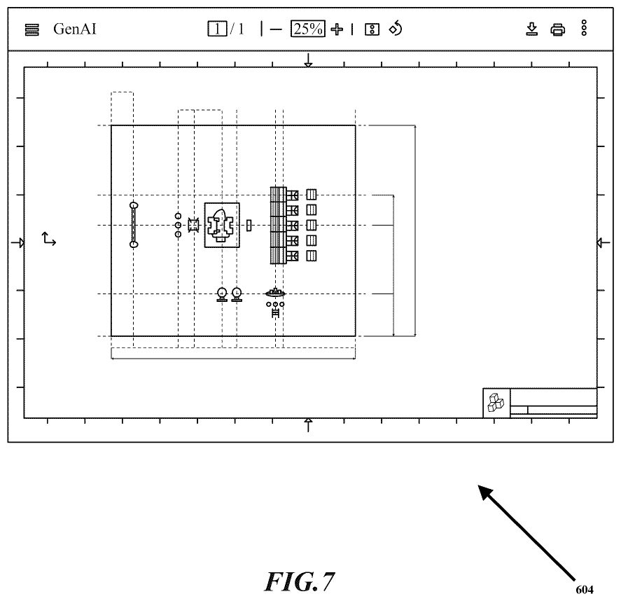

FIG. 7 presents the generated 2D plan view 604 in an embodiment, displaying the layout configuration and technical specifications of the proposed design.

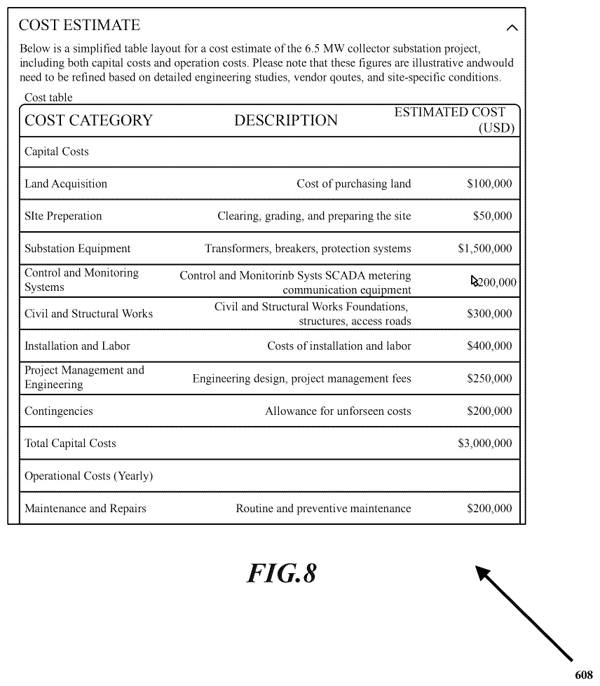

FIG. 8 depicts the cost estimate table 608 in an embodiment that provides the project costs into categories including capital costs, operational costs, and total estimated costs.

These components work together through a cloud-based infrastructure to transform user inputs into comprehensive infrastructure proposals, with the user interfaces enabling intuitive interaction while the backend processing modules handle design generation and proposal creation.

This system in its preferred embodiment leverages artificial intelligence (AI) to automate and optimize the creation of modality layouts for utilization in associated engineering proposals as an output. The core technologies underpinning this system include lightweight generative or rendering pipeline, generative models selected from the group consisting of diffusion, transformer-based, GAN, or other deep generative architectures, and a hybrid retrieval pipeline using dense, sparse, or graph embeddings and post-retrieval re-ranking or answer verification architecture utilizing large language models (LLMs). Additionally, the system in an exemplary embodiment incorporates AI agent functions that further enhance its capability to produce optimized designs under a variety of constraints and specifications. At the core of the preferred embodiment is the integration of generative models with large language models (LLMs) employing a hybrid retrieval pipeline using dense, sparse, or graph embeddings and post-retrieval re-ranking or answer verification. This combination allows the system to understand and apply complex regulatory and operational standards specific to modality design. The generative model component is responsible for generating visual proposals based on the input parameters, while the LLMs handle the textual and compliance aspects, ensuring that all proposals meet the required standards and specifications.

In the preferred embodiment, the system comprises a lightweight generative or rendering pipeline. This component of the system facilitates generation of initial design layouts based on the inputs provided to the system. It works by encoding various input parameters into a latent space, from which it can generate numerous potential designs. This process ensures that the system can generate design solutions as an output that are tailored to the specific conditions of each project based on the input parameters.

In an embodiment, the system comprises the application of deep learning algorithms to explore a range of design possibilities/solutions for inclusion into a proposal generated as an output of the system based on the input data. This application is facilitated by the lightweight generative or rendering pipeline.

The hardware infrastructure supporting this process includes computing systems equipped with powerful CPUs and GPUs, which in accordance with an embodiment comprise cloud-based backend infrastructure. These systems are essential for handling the computational complexity of deep learning algorithms. The GPUs, in particular, in accordance with an embodiment accelerate the mathematical computations required for training and running deep learning models, thereby significantly reducing the time it takes to generate design options for inclusion into a proposal as an output in accordance with an embodiment.

The cVAE utilizes deep learning algorithms to process and interpret the input data, which in an embodiment comprises geographical location, site dimensions, environmental constraints, and specific electrical standards. These algorithms are capable of understanding complex patterns and dependencies in the data, which are not readily apparent through traditional analytical methods. The cVAE operates by encoding the input data into a lower-dimensional latent space and then decoding it to generate new data points. This process allows the cVAE to learn a representation of the input data, capturing its essential characteristics. Once trained, the cVAE can generate a variety of potential design layouts by sampling from the latent space. Each sample represents a different combination of the learned features, thus providing a range of possible design solutions for inclusion into a proposal as an output in accordance with an embodiment.

The exploration of design possibilities is achieved by manipulating the conditions under which the cVAE generates the new data points. For instance, by varying the encoded parameters related to the geographical constraints or electrical requirements, the system can produce different modality layouts that still adhere to the overall design principles but differ in specific aspects such as the arrangement of components to meet engineering standards or the utilization of space.

This capability to generate multiple design options for inclusion into a proposal as an output in accordance with an embodiment from a set of input parameters is particularly valuable in the early stages of the proposal generation process. It allows a user to quickly visualize potential solutions and make informed decisions about which designs to pursue further for inclusion into a proposal as an output of the system. This not only accelerates the design and proposal development process but also enhances creativity and innovation by providing a broader array of options.

The generated designs are then processed further by backend systems, which in an exemplary embodiment comprise cloud-based backend infrastructure for data storage and additional computational resources. These systems support the further refinement and evaluation of the designs generated by the cVAE, using more detailed models and simulations. The integration with cloud-based backend infrastructure systems ensures that the data flow between the different components of the proposal generation system is seamless and that the computational resources are scalable according to the project's demands.

In another aspect, the preferred embodiment of the system comprises a generative model. Each generative model is employed to refine the designs generated by the lightweight generative or rendering pipeline. Through an adversarial process, the generative models iteratively improve the designs by aligning them more closely with the desired output criteria. Such mechanism is useful to refine and optimize the precision and feasibility of any of the proposed layouts generated as an output by the system.

In another aspect, the preferred embodiment of the system comprises a hybrid retrieval pipeline using dense, sparse, or graph embeddings and post-retrieval re-ranking or answer verification Architecture Using a large-language-model (LLM) or multi-modal foundation model capable of tool invocation. The hybrid retrieval pipeline component utilizes LLMs to handle the textual and compliance aspects of the design. It retrieves relevant data and past project examples to inform the design process. In such manner, the system generates as outputs that meet regulatory standards and best practices that comprise training inputs for the system. This integration of retrieval-augmented capabilities with generative models empowers the system to produce innovative, compliant and technically sound proposals as outputs.

In another aspect, the preferred embodiment of the system comprises one or a plurality of AI Agents. These AI Agents act as the orchestrators within the system, managing the interaction between different AI components and ensuring that the output is synchronized and optimized. The AI agents monitor the performance of each design iteration, making adjustments as necessary to ensure that the outputs produced by the system align with the project specifications as inputs more effectively.

In an exemplary embodiment, the operational flow of the system begins with the input of project-specific parameters, followed by the generation of initial design concepts using the cVAE. These concepts are then refined through the cGANs to enhance their quality and feasibility. Concurrently, the RAG-LLMs component works to ensure that all designs adhere to the necessary regulatory and technical standards. Throughout this process, AI agents oversee the system's operations, ensuring efficiency and alignment with project goals. As such, the system in an embodiment acts as a collaborative AI partner in the engineering design process for a user.

The system in an aspect comprises calibration to receive as inputs from a user and subsequently interpret complex design requirements and regulatory standards, translating these into highly optimized, compliant, and cost-effective modality layouts. The system functions by receiving input parameters that define the specific needs and constraints of a modality project, such as geographical location, electrical capacity requirements, environmental considerations, and regulatory compliance needs.

In an exemplary embodiment, the input parameters for the system include geographical constraints, which may comprise geolocational coordinates, the size and shape of the land area available for the modality, and electrical requirements, such as capacity and connectivity needs. Additionally, in the preferred embodiment, the artificial intelligence aspects of the system are trained on a dataset comprising regulatory standards and safety requirements, which the system incorporates to generate designs and other outputs in compliance with such regulatory standards and safety requirement. An aspect of the invention comprises training the system with updates as new regulations come into effect, allowing the system to adapt to changes in the regulatory landscape. Once the input parameters are provided to the system, optionally as in an exemplary embodiment by a user within a chat via an associated user interface such as that depicted by FIG. 3, it generates multiple modality layout proposals. These proposals are optimized for various factors, including cost-efficiency, operational efficiency, and minimal environmental impact. The system evaluates each design against the input criteria and iterates on the designs to enhance their quality and compliance further.

The input interface of the system serves as the primary gateway through which users interact with the AI-driven generative design system. In the preferred embodiment, aspects of the system are configured as a front-end software as a service (SaaS) platform facilitating the generation of proposals related to the design of electrical substations. In such manner the system in an example is highly adaptable, capable of collecting a wide array of necessary parameters that influence the design of electrical substations. In exemplary embodiment, questions and prompts generated by the system within a chat user interface as depicted in FIG. 3 are instrumental in ensuring that all relevant needed data is accurately captured from the user and effectively utilized by the system's AI components. In various examples, the user interface and/or other input mechanisms such as webhooks and API linkages are engineered to accommodate various data types and sources, providing flexibility and comprehensiveness in data integration within the system. In an embodiment, users can manually enter specific project details such as the size of the land area, expected electrical load, and specific client requirements through direct user input such as within a “Project Details” view as depicted in FIG. 1. This ensures that the system has all the fundamental data inputs necessary to begin the design process as intended to deliver the desired proposal output. Additionally, in an exemplary embodiment the user interface includes a streaming chat feature to facilitate real-time communication and data exchange as depicted in FIG. 3. This aspect of an embodiment allows project stakeholders to discuss and input data directly into the system during planning meetings or collaborative sessions, ensuring that all relevant information is immediately captured and considered. In an exemplary embodiment, the system is also equipped with a feature to query and retrieve the latest regulatory and safety standards applicable to modality design, optionally depicting such standards within in aspect of the user interface. This ensures that all proposals along with the preliminary designs generated by the system are up-to-date with current regulations and compliance requirements.

Moreover, the system in its preferred embodiment integrates with external mapping platforms, weather and environmental services including geographic information systems (GIS) and Building Information Modeling (BIM) to enhance its data gathering capabilities. By integrating with geographic information systems (GIS) such as those offered by Environmental Systems Research Institute, Inc. (Esri), various aspects of which are described in U.S. Pat. No. 9,785,728 granted on Apr. 12, 2016, U.S. Pat. No. 9,851,209 granted on Dec. 26, 2017, U.S. Pat. No. 9,411,967 granted on Aug. 9, 2016, U.S. patent application Ser. No. 15/213,143 filed on Jul. 18, 2016, and other related systems such as that described in U.S. Pat. No. 6,061,688 granted on May 9, 2000, each of which are hereby incorporated by reference in their entirety, the system can, via well-known-in-the-art computing and networking aspects designed to facilitate communicative connection such as API connectivity, access detailed geographical and infrastructural data crucial for planning the physical layout of modalities, including topographical data, existing utility networks, and environmental constraints. In another exemplary embodiment, integration with external open source geoinformation providers and GIS such as OpenStreetMap provides access to a broad, user-generated source of geographical data, offering additional layers of context that can influence design decisions, such as community land use and public infrastructure. Additionally, integration with systems comprising 3D modeling and 3D models analysis tools, such as in an exemplary embodiment with Autodesk Forma and/or the tools described in U.S. patent application Ser. No. 17/229,320 filed on Apr. 13, 2021, Ser. No. 17/990,301 filed on Nov. 18, 2022, Ser. No. 16/837,618 filed on Apr. 1, 2020, Ser. No. 18/058,121 filed on Nov. 11, 2022, and Ser. No. 17/238,116 filed on Apr. 22, 2021 and U.S. Pat. No. 9,773,023 granted on Sep. 26, 2017, 9,002,946 granted on Apr. 7, 2015, and 6,999,102 granted on Feb. 14, 2006 which are hereby incorporated by reference in their entirety (and in combination with other CAD-related technologies produced by Autodesk, Inc. and its competitors, referred to herein as “Autodesk-Related Systems”), enables the system to utilize advanced 3D modeling tools and resources, facilitating the creation of detailed, accurate visual representations of proposed modality designs.

In alternative embodiments of the invention, the system interacts with or integrates with Building Information Modeling (BIM) and other 2D/3D modeling programs from various vendors to enhance the design and proposal generation process for electrical substations. BIM, for instance, offers a collaborative environment that not only provides detailed digital representations of physical and functional characteristics of facilities but also allows for the integration of various data inputs throughout the construction lifecycle. By incorporating BIM, the system could leverage its detailed layering and parametric data capabilities to further refine modality designs, ensuring that they are not only compliant with regulatory standards but also optimized for construction and operational efficiency. Additionally, in embodiments, the interaction with or integration of alternative 2D/3D modeling programs such as Autodesk, Bentley Systems, Dassault Systemes, or Trimble provide additional flexibility and choice in the design tools used, potentially offering unique features or better integration with specific types of infrastructure projects.

The preferred embodiment of this invention is designed to be technologically neutral with respect to the specific CAD, GIS, and BIM technologies employed, as well as the AI LLM/APIs utilized. It is compatible with a wide array of 3D modeling programs, ensuring that it can be practiced with any system that meets the basic functional requirements. This flexibility is a core aspect of the invention, allowing it to seamlessly integrate with various industry-standard and specialized design tools, regardless of the vendor. Whether an engineering firm prefers Autodesk, Bentley Systems, Dassault Systemes, Trimble, or any other software provider, the system can adapt to incorporate these tools into its workflow. This technology-neutral approach not only broadens the applicability of the invention across different sectors and projects but also ensures that it remains adaptable to future advancements in design and modeling technologies.

To illustrate the versatility and depth of the input interface in accordance with the preferred embodiment, an example contemplates the design of a modality in a densely populated urban area. The system in an embodiment comprises integrated data collected from Esri as referenced herein to assess existing electrical infrastructure and integrated data collected from OpenStreetMap for understanding local building densities and traffic patterns. The system can then utilize such data in designing a modality that minimizes disruption to the community that further aligns with urban planning regulations in accordance with the system's earlier training. In another exemplary use, the system may be utilized to generate a proposal for a project aiming to integrate renewable energy sources in a rural area, which may generate renderings of such projects as shown in FIG. 4 and FIG. 6 within a user interface in an exemplary embodiment. In accordance with such example, the system may utilize Autodesk Forma and other Autodesk-Related Systems to simulate the impact of new technologies within the landscape. Direct user inputs regarding local climate data and renewable energy targets can also be factored into the design to optimize performance and sustainability. Furthermore, when a new safety regulation is passed, the system in an embodiment comprises an aspect to automatically update all ongoing projects with inputs related to such new safety regulation to ensure compliance. This regulation monitoring feature generates proposals that incorporate efforts to facilitate compliance with up-to-date regulations and helps to avoid delays in project approvals and ensures all designs meet the latest known safety standards.

As an aspect of an embodiment, the streaming chat component of the system facilitates the collection of input by the system. The streaming chat component, as depicted within the context of a user interface in an exemplary embodiment within FIG. 3., in an embodiment comprises an interaction tool enhances the efficiency of data input into the AI-driven generative design system. This aspect of the system leverages an architecture that utilizes a Retrieval-Augmented Generation (RAG) with multi-agent Large Language Models (LLMs), in an example specifically trained on standards and specifications pertinent to modality design. This training enables the chat system to understand and process complex technical language and regulatory requirements relevant to modality design, ensuring that the data collected and the responses provided by the system in the context of the streaming chat component are relevant and precise.

In an exemplary embodiment, the system comprises an integration of technologies such as APIs provided by OpenAI, which in various aspects are described by or relate to the technologies described in U.S. Pat. No. 11,922,550 granted on Mar. 5, 2024; 11,922,144 granted on Mar. 5, 2024; 11,886,826 granted on Jan. 30, 2024; and 11,887,367 granted on Jan. 30, 2024; and U.S. patent application Ser. No. 18/321,852 filed on May 23, 2023 and Ser. No. 18/321,921 filed on May 23, 2023 (and in combination with other AI-related technologies produced by OpenAI and its competitors, referred to herein as the “OpenAI-Related Systems”) to facilitate the streaming chat component and other generative AI aspects associated with the system. Such OpenAI-Related Systems enable implementation of natural language processing capabilities within the chat system. Through the OpenAI-Related Systems, the chat interface can interpret user queries and statements, regardless of their complexity or the technicality of the language used. In an embodiment, this capability forming an aspect of the system enables the accurate capture and interpretation of the detailed and technical input required for modality proposals.

In an exemplary embodiment of the system, the employed architecture combines a Retrieval-Augmented Generation (RAG) with Large Language Models (LLMs), alongside custom agents and functions enabled via OpenAI-Related Systems. Such configuration facilitates a streamlined approach to capturing a user's proposal requirements. Initially, the system engages users through an interactive chat interface, such as that depicted by FIG. 3, where the RAG/LLM architecture plays a crucial role in understanding and processing user inputs. This interaction is enhanced by custom agents including those facilitated via OpenAI-Related Systems, which are adept at interpreting the nuances of requirements provided to the system as inputs and translating them into structured queries that the system can process.

Once the requirements are captured by the system as inputs, they undergo a cleaning and formatting process. This step provides that the data is not only accurate but also formatted in a manner that is compatible with the backend processes associated with the system. The cleaned data is then ready to be utilized by the backend components, specifically the conditional Variational Auto-encoders (cVAE) and conditional Generative Adversarial Networks (cGAN), which are responsible for generating the initial and refined designs of the electrical substations as described herein.

The system's architecture in accordance with the preferred embodiment designed as a Software as a Service (SaaS) model, supported by robust backend web services. This architecture allows for seamless integration with several other industry-standard platforms such as Esri and Autodesk, including as described herein. Such integrations enable the system to access a wide range of geographical and design data, enhancing the system's capability to generate more accurate and compliant modality designs.

The development of the AI components is carried out in accordance with the preferred embodiment implemented in one or more ML frameworks such as PyTorch 2.x, TensorFlow, JAX, or their successors. These frameworks support machine learning and neural network development, important for the functioning of the lightweight generative or rendering pipeline and generative models in association with an embodiment of the system. Additionally, the streaming chat capabilities powered by OpenAI-Related Systems facilitate user interaction, making the data capture process via associated user interfaces, such as that depicted by FIG. 3, more efficient and user-friendly.

Supporting the entire system in accordance with the preferred embodiment is a cloud-based backend infrastructure. The cloud infrastructure is crucial as it facilitates the handling large datasets and the computational demands of generating modality designs. The cloud-based services, which may be provided by cloud infrastructure providers including but not limited to Amazon Web Services (AWS), Microsoft Azure, Google Cloud Platform (GCP), and IBM Cloud, ensure that the system can process data quickly and reliably, providing users with timely and accurate design proposals. This backend configuration not only supports the scalability of the system but also ensures its reliability and availability, making it a robust solution for the design and proposal of electrical substations. In various embodiments, the cloud-based backend infrastructure serves as the aspect of the system for managing the extensive datasets and computational demands associated with generating modality designs. The cloud-based backend infrastructure facilitates processing complex tasks such as those performed by the generative models and lightweight generative or rendering pipeline in accordance with the system. Furthermore, the integration of various data sources and third-party services as an aspect system are facilitated by such cloud-based backend infrastructure. The cloud infrastructure providers offer APIs and tools for seamless integration, ensuring that the system can efficiently access and utilize up-to-date geographic data, structural models, and other relevant information including as described elsewhere herein. These integrations enable the electric substation design process and proposal generation process with accurate and comprehensive data as an aspect of the preferred embodiment.

In accordance with embodiments, AWS provides a range of compute options that exceed the requirements for generating and refining multiple design iterations quickly and thereby facilitate the generation of proposals as an output of the system. Similarly, Microsoft Azure and Google Cloud Platform can distribute the computational load effectively across their networks in accordance with alternative embodiments of the system. Such capabilities of the cloud-based backend infrastructure facilitate processing complex tasks such as those performed by the conditional Generative Adversarial Networks (cGAN) and conditional Variational Auto-encoders (cVAE) in accordance with the system. Furthermore, the integration of various data sources and third-party services as an aspect system are facilitated by such cloud-based backend infrastructure. AWS, Azure, and GCP all provide APIs and tools for seamless integration, ensuring that the system can efficiently access and utilize up-to-date geographic data, structural models, and other relevant information including as described elsewhere herein. These integrations enable the electric substation design process and proposal generation process with accurate and comprehensive data as an aspect of the preferred embodiment.

In another aspect, the streaming chat functionality, enabled by communicatively connected OpenAI-Related Systems in an embodiment of the system, seamlessly interacts with the system's AI agent functions. These agent functions are configured in an embodiment to control the flow of the chat, guiding the conversation in a way that ensures all necessary criteria are discussed and captured. For instance, in accordance with an intended use of the preferred embodiment, if a user begins to discuss the electrical capacity requirements of a new modality, the AI agent can prompt the user for specific details related to the training of the models associated with the system, such as peak load requirements or preferred connectivity options. This targeted questioning helps in gathering comprehensive and precise data without overwhelming the user. Once the necessary criteria are extracted during the chat sessions, the AI agents transfer this data as an input to other backend services of the system, specifically in an embodiment the conditional variational auto-encoders (cVAE) and conditional generative adversarial networks (cGANs). These backend services are responsible for generating the initial design layouts and refining them to meet the specified requirements in accordance with an embodiment. The seamless transfer of data from the streaming chat to these services is facilitated in accordance with various embodiments by data protocols and APIs as understood in the art that ensure data integrity and security. The streaming chat feature not only enhances user interaction but also significantly speeds up the data collection process enabling inputs into the system. By allowing real-time data input and interaction, the system can quickly gather all necessary information to begin the design process important for the generation of a proposal as an output. The present inventors have recognized that such efficiency is particularly beneficial in scenarios where time constraints are an important consideration by a user, such as in the context of competitive bidding situations or when adherence to strict project timelines is relevant.

Various embodiments of the system further comprise aspects to facilitate the generation of project proposals. In an exemplary embodiment, the conditional Variational Auto-encoder (cVAE) component of the system facilitates the initial stages of the proposal generation process. In one aspect, the cVAE is utilized to quickly generate previews of the proposal layout in the form of 2D plan view drawings. This capability is particularly valuable in the context of an embodiment of the system as it provides a much faster alternative to the more time-intensive processes involved in generating detailed 3D models and comprehensive 2D drawing sets that are typically used in final proposal stages. The system's use of cVAE for generating preliminary 2D layouts allows for rapid feedback loops with the users in accordance with an exemplary embodiment. When project parameters are input into the system, the cVAE generates multiple layout previews, each representing a potential solution based on the specified conditions and constraints. These previews are presented to the users in a visually accessible format, such as in an embodiment as depicted by FIG. 3, enabling them to quickly assess the viability and effectiveness of each proposed layout in the context of their specific project needs.

In an aspect of the system, the generation and presentation of multiple design options facilitate user engagement and decision-making efficiency. In accordance with an exemplary embodiment, users can select from a plurality of preliminary designs via a user interface of the system that best meet their criteria or that they find most promising for further incorporation into a proposal output. Once a selection is made by a user, the chosen designs can then be processed through the conditional Generative Adversarial Network (cGAN) to develop detailed 3D models and complete 2D drawing sets for inclusion into a proposal output. In accordance with an exemplary embodiment, such user interactions are essential for the final stages of the proposal process, where precision, compliance, and completeness as directed by a user are important.

In accordance with the architecture of the preferred embodiment of the system, the cGAN serves an important role for generating proposals for electrical substations. The cGAN component of the system initiates following a user's selection of one or more preliminary designs initially generated by the conditional Variational Auto-encoder (cVAE), in accordance with a preferred method of use. The cGAN then refines these selections into detailed 3D models and comprehensive 2D drawing sets for inclusion within the proposal as an output of the system.

The cGAN comprises two primary functionalities in accordance with the preferred embodiment: the Generator and the Discriminator. The Generator serves as the creative engine, as calibrated by the input parameters provided to the system-such as geographical constraints, electrical requirements, and specific regulatory standards, along with training and other predefined inputs not provided by the system's user—to simulate realistic modality layouts. These parameters are informed by the preliminary selections and in accordance with the preferred embodiment are deeply rooted in modality design principles, ensuring that the layouts generated by the cGAN Generator remain practical and tailored to the specific needs of the project in accordance with the input parameters.

The Discriminator functions as the critical evaluator within the cGAN. It assesses each design produced by the Generator against a set of predefined criteria and training of the system, in accordance with the preferred embodiment focusing on feasibility, compliance with regulatory standards, and optimization of the layout for performance and cost. This evaluation acts as a quality control mechanism, filtering out any designs that do not meet the desired standards. The present inventors have found that in accordance with such aspects of the preferred embodiment, the final proposals are not only technically sound and aesthetically pleasing but also compliant with relevant regulations and optimized for the specific conditions of the project.

In embodiments of the system, the interaction between the Generator and the Discriminator is dynamic and iterative. The Generator proposes designs, which are then evaluated by the Discriminator. If a design fails to meet the necessary standards, including standards that are defined in accordance with inputs provided to the system, feedback is provided to the Generator, prompting adjustments in the design parameters. In an exemplary embodiment, adjustments in the design parameters may be provided by a user following review of a design via a user interface associated with the system as a step in the process of the loop. This loop continues until the designs satisfy all criteria for quality and compliance.

Once the designs have been refined and approved through this iterative process, they are rendered into detailed 3D models and developed into complete 2D drawing sets, in an example such as those depicted by FIGS. 4, 6, and 7. These final outputs are included within the generated proposal in accordance with an embodiment, as they provide a clear, detailed, and tangible representation of the proposed modality as an element of the proposal generated as an output in accordance with the preferred embodiment.

An inventive aspect associated with the system in the embodiment comprises a method of generating a proposal. Collecting data is the first step in accordance with an embodiment, where the input interface actively gathers and preprocesses essential data such as geographical location, site dimensions, environmental constraints, and specific electrical standards. This stage is crucial for setting a solid foundation for the subsequent design phases, ensuring that all relevant parameters are accurately captured and structured for effective use.

The step of generating designs follows in an embodiment, with the cleaned and structured data being fed into the generator component of the cGAN. Here, the generator employs deep learning algorithms to create several design options based on the input parameters. This step leverages the power of artificial intelligence to explore a wide range of design possibilities, effectively translating the input data into potential modality layouts.

The step of evaluating designs is the next step, where each generated design is assessed by the discriminator. This component checks each design for compliance with technical standards, environmental regulations, and integration capabilities with existing infrastructure. The discriminator ensures that only viable designs are considered for further refinement, acting as a filter to maintain high standards of quality and feasibility.

The step of optimizing designs through an iterative loop involves refining designs that meet the initial criteria. This optimization loop fine-tunes each design for enhanced performance, cost-efficiency, and regulatory compliance. It can incorporate feedback from engineers and stakeholders, allowing for a collaborative and progressive refinement of the designs. This iterative process is important to achieving the optimal content within the generated proposal, including in terms of both functionality and compliance.

In accordance with the step of generating design option choices in parallel with the optimization loop, the cVAE produces images of 2D plan views, such as depicted in an exemplary embodiment in FIG. 7, using the design criteria as conditions. This allows users to quickly preview designs and select those that are closest to meeting their final proposal requirements. The ability to rapidly visualize multiple design options has been recognized by the present inventors as significantly enhancing decision-making efficiency by the user of the system and improving user engagement.

The step of selecting the final design involves presenting the best-performing designs to a user through a 3D map user interface, such as that depicted in an exemplary embodiment by FIG. 4. This interface allows for final adjustments and approvals, providing a platform for stakeholders to visualize and modify the designs before finalization. This step ensures that the selected designs fully meet the project's requirements and stakeholder expectations.

In accordance with an embodiment of the method, the last step comprises generating the final proposal as the culmination of the process, during which a cGAN generates detailed proposals based on all the criteria established in the previous steps, the LLM-trained data, specific templates chosen by the user, and in accordance with an intended utilization, criteria outlined per electrical substation type. The final proposal includes sections matching the end-user template along with multiple 2D drawings optionally comprising the plan view, multiple elevations, and a foundation. Such documentation provides the proposal is ready or near ready for implementation, providing required details for construction and compliance verification by a reader of the proposal.

Furthermore, in accordance with an exemplary embodiment of the system and its associated methods of use, the ability of the system to quickly generate and iterate on 2D plan view drawings, such as that depicted by FIG. 6, for inclusion in the proposal has been found by the present inventors to significantly reduce the initial time and resource investment typically otherwise required in the early phases of proposal development. Such efficiency as provided by the system not only accelerates the proposal generation process but also allows for greater flexibility in exploring different design alternatives. By enabling rapid prototyping and revisions to generated designs relevant to proposals as directed by a user via a user interface in an exemplary embodiment of the system, the cVAE component helps ensure that the final proposals are closely aligned with the project's requirements and constraints, including those that are provided as inputs by a user, such as via a chat interface in an exemplary embodiment as depicted in FIG. 3.

In an embodiment, the system comprises the ability to learn from each project. By analyzing completed projects and ongoing design data previously associated with the system during the generation of proposals, the system continuously refines its understanding of effective design practices and regulatory compliance. This learning process allows the system to make increasingly accurate predictions and suggestions, improving the efficiency and success rate of proposal projects over time.

By automating critical aspects of infrastructure modality planning and proposal generation, the system significantly enhances the efficiency and accuracy of these processes. This is achieved through the integration of AI components like conditional Generative Adversarial Networks (cGAN) and conditional Variational Auto-encoders (cVAE), which facilitate rapid generation and refinement of design proposals. Additionally, the use of a cloud-based backend infrastructure ensures that the system can handle large datasets and complex computational tasks with ease, further enhancing the speed and reliability of the proposal process. The automation provided by this system allows for more efficient proposed responses to the demands of modern electrical infrastructure development. As the need for more sophisticated and reliable energy solutions grows, the ability to quickly and accurately generate modality proposals becomes increasingly important. This system not only meets this need but does so in a way that allows for significant scalability and adaptability, accommodating future advancements in technology and changes in regulatory requirements.

Moreover, the system's integration with external platforms and its ability to process and incorporate a wide range of data inputs ensure that each proposal generated by the system not only facilitates compliance with current standards but also optimized for performance and cost-efficiency. This approach not only streamlines the workflow for engineers and designers and provides the tools necessary to make informed decisions that align with strategic business objectives and regulatory frameworks. The present inventors have found that the system enhances and streamlines the process of modality proposal generation. By significantly reducing the time required to produce compliant and optimized proposals, the system enables engineering firms to respond more quickly to RFPs and increase their chances of proposals that facilitate the execution of engagements with clients. The enhanced efficiency, accuracy and compliance of the proposals generated as an intended output of the system minimizes costs and optimizes the likelihood of engagement following delivery.

In an embodiment of the invention, the output generated by the system extends beyond mere proposal documentation. In such embodiment, the output serves as a preliminary design of the solution that can be further detailed using various design tools once a particular alternative or solution is selected. This embodiment of the system ensures that the output is produced in industry-supported 2D/3D data formats, which are compatible with many design tools commonly used in the utilities sector. This compatibility facilitates seamless integration into subsequent stages of the design and development process, allowing utility companies to efficiently transition from proposal to detailed design phase without the need for data conversion or re-entry. The ability to directly input these outputs into design tools not only streamlines the workflow but also reduces the potential for errors and miscommunications, thereby enhancing the overall efficiency and reliability of utility operations. This aspect of the embodiment underscores the practical utility of the invention within utilities workflows, justifying its adoption and implementation across various projects within the sector.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

We claim:

1. A system for generating proposals for infrastructure modalities, comprising:
an input interface configured to receive and preprocess data including geographical location, site dimensions, environmental constraints, and specific electrical standards;
a lightweight generative or rendering pipeline configured to generate preliminary 2D plan view designs based on the preprocessed data;
a generative model selected from the group consisting of diffusion, transformer-based, GAN, or other deep generative architectures comprising a generator and a discriminator, wherein:
the generator is configured to create 3D models and 2D drawing sets from selected designs, and
the discriminator is configured to evaluate the generated designs against predefined criteria;
a cloud-based backend infrastructure provided by one or more cloud infrastructure providers configured to support data processing and integration with third-party services;
wherein the system is configured to generate optimized modality design proposals in response to user inputs.

2. The system of claim 1, wherein the input interface includes a user interface configured to display the preliminary 2D plan view designs and receive user selections of the designs for further processing by the generative model.

3. The system of claim 1, wherein the generator utilizes input parameters comprising the user inputs, geographical constraints, construction standards and electrical requirements to simulate realistic infrastructure layouts.

4. The system of claim 1, further comprising a hybrid retrieval pipeline using dense, sparse, or graph embeddings and post-retrieval re-ranking or answer verification for integration with geographic information systems (GIS), weather and environmental services and design tools for enhancing data accuracy and design detail.

5. A method for generating a proposal for infrastructure modality design, comprising:
collecting data related to a proposed modality site, including geographical location, site dimensions, environmental constraints, and specific standards;
generating preliminary 2D plan view designs of the modality using a lightweight generative or rendering pipeline based on the collected data;
selecting one or more of the preliminary designs;
refining the selected designs into detailed 3D models and complete 2D drawing sets using a generative model selected from the group consisting of diffusion, transformer-based, GAN, or other deep generative architectures that evaluates and optimizes the designs;
generating a final proposal comprising the optimized modality design, including 2D drawings and a 3D model in preliminary design.

6. The method of claim 5, wherein generating preliminary 2D plan view designs includes applying deep learning algorithms implemented in one or more ML frameworks selected from PyTorch 2.x, TensorFlow, JAX, or their successors to explore a range of design possibilities based on the input data.

7. The method of claim 5, wherein refining the selected designs includes an iterative process between the generator and discriminator components of the generative model to enhance design accuracy and compliance with regulatory standards.

8. The method of claim 5, further comprising integrating feedback from engineers and stakeholders during the refining step to incorporate practical insights and requirements into the modality design.
